(19) United States
(12) Patent Application Publication
(10) Pub. No.: US 2004/0209458 A1
(43) Pub. Date: Oct. 21, 2004

(54) Semiconductor device having rounding profile structure for reducing step profile and manufacturing processing stress and its manufacturing method

(76) Inventors: Shin Yi Tsai, Hsinchu (TW); Chun Yi Yang, Chu Tong Town (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/414,087

(22) Filed: Apr. 16, 2003

(51) Int. Cl. H01L 21/4763

(52) U.S. Cl. 438/637

(57) ABSTRACT

The present invention discloses a semiconductor device having a rounding profile structure for reducing the step profile and the manufacturing processing stress and a method for rounding the corner of the membrane element in a semiconductor device. In the present invention, a membrane is deposited on a semiconductor substrate, then after a photo-resist pattern transferring step, dry etching step, and photo-resist removing step, a patterned membrane element is formed thereon. Then, a sacrificing layer is formed conformally overlaying the patterned membrane element, wherein the sacrificing layer is step height according to the patterned membrane element. Following, an etching back step is performed to etch the sacrificing layer by selectivity etching to form a rounding profile of the coroner of the membrane element. Last, the residual sacrificing layer is removed. The present invention not only can solve the over etching problem of the prior technology with the difficult of directly etching to form the rounding corner, but also can broaden the follow-up processing window and improve the reliability and yield ration of the products of the follow-up processes.

### BACKGROUND OF THE INVENTION

1. Field of the Invention

The present invention generally relates to a semiconductor structure and its manufacturing method, and more particularly relates to a semiconductor device having a rounding profile structure for reducing the step profile and the manufacturing processing stress and a method for rounding the corner of the membrane element in a semiconductor device.

2. Description of the Prior Art

Accordingly, the semiconductor manufacturing process is developed become the multi-layer stacking profile process because of the high integrated development trend of the integrated circuits. Hence, the manufacturing process become more complex and high-accuracy required, such as the smooth and evenness of the etched profile. If the profile is step height, it causes the permanence mechanical damage of membrane peeling, membrane cracking result from the accumulating stress of membranes and to lessen the follow-up processing window so as to reduce the reliability and yield ration of the products of the processes. So, the smooth and evenness of the etched profile is become one important consideration in the current semiconductor manufacturing process.

Referring to the FIG. 1, it discloses a schematic representation of the cross-section view of the semiconductor structure, in accordance with prior techniques. A membrane is deposited on a semiconductor substrate 10. Then, a photolithography process is preformed on the membrane to form a patterned membrane element 12, wherein the mentioned membrane element 12 can be any kinds of semiconductor devices. The patterned membrane element 12 is provided with a approach right angle profile so as easily to cause the cracks, peeling, voids of the deposited membrane because of high stress and further to effect the yield ration of the products of the process. The profile is rise and fall to cause the high step height to lessen the follow-up processing window and to increase the difficult of the follow-up processes,

In order to prevent the mentioned problem of the undercut, an improved technology of prior semiconductor structure is developed, such as the cross-section view of the FIG. 2. A membrane is deposited on a semiconductor substrate 20 and then a photolithography process is performed on the membrane to form a membrane element 20 with an approach right angle profile, such as shown in the Drawing A. Then, the membrane element 22 is etched by directly etching to form the membrane element 24 with a rounding profile, such as shown in the Drawing B. Etching methods for forming the rounding profile are divided to a wet etching method and a dry etching method. The wet etching method is an isotropic etching step and easily to cause the undercut effect of a portion of the membrane element. The difficult control of the profile of the etched membrane element will cause high step height and harmful effect of the follow-up processes.

Anther dry etching method is an anisotropic etching step. Although it can reduce the undercut effect, but it usually accompanies strong ion bombardment by dry etching with plasma, which will generate the plasma damage causing the electronic damage and the structure damage so as to affect the reliability of the semiconductor device.

Referring to FIG. 4, a schematic view of a prior art semiconductor memory is illustrated. In a surface of a semiconductor substrate 10, a plurality of semiconductor elements with tip shapes and vertical sides are formed. Next, a dielectric layer 14 covers on the exposing surfaces of an element 12 and the semiconductor substrate 10. The element 12 may be a BD (Berry Diffusion) oxide layer, Metal-Interconnect wires, an etched patterned thin film, or a rectangular element with a tip and lateral sides. The dielectric layer is generally selected from one of the silicon dioxide, silicon oxide, or tetraethyl-orthosilicate, boronitrosilicate glass, or nitrosilicate glass, tetraethyl-orthosilicate, silicon saturation silicon oxide, etc.

The prior art memory structure illustrated in FIG. 4 has the following disadvantages.

Since the element 12 has a tip angle and vertical sides, the dielectric layers at the upper surface and lateral sides of the element 12 will become too high so as to induce cracks, hillocks, or pealing effect so that problems about the stability and yield of the elements will be induced.

Since the size of an element become smaller and smaller. A gap between each two elements 12 will reduce further so that the following step of depositing the dielectric layer 14 is hard to be executed. The voids 16 illustrated in FIG. 5 is easy to leave in the gaps of the element 12, thereby, unfavorable effect occurring in the following process. Since the element 12 has tips and vertical sides so that the step height of the dielectric layer 14 is too large. The incomplete etching will occur in the succeeding process. Furthermore, in the following process, since the window is too small and the difficulty in focus occurs so that the precision and resolution in transferring a lithographic pattern is affected, thereby, some disadvantages occurring in the succeeding etching process.

Therefore, there is an eager demand for a novel semiconductor rounding profile for reducing step profile and manufacturing processing stress so as to increase the tolerance in the succeeding manufacturing process.

Owing to the difficult control of the formulation of the semiconductor rounding profile by prior technology by directly etching method, obviously, the main spirit of the invention is to provide a semiconductor device having a rounding profile structure and its manufacturing method for rounding the corner of the membrane element in the semiconductor device, and then some disadvantages of step height and high stress of well-known technology are overcome.

### SUMMARY OF THE INVENTION

The primary object of the present invention is to provide a method for rounding the corner of the membrane element in the semiconductor device to solve the over etching problem of the prior technology with the difficult control of directly etching to form the rounding corner. The present invention utilizes the organic component for the sacrificing layer and the material is easy for reworking so as to offset the inaccuracy of the photolithography step. The present invention can prevent the permanence damage by the following processes and the organic component provides with the advantages of better coating and uniform conformity.

Another object of the present invention is to provide a method for rounding the corner of the membrane element in the semiconductor device. So the rounding profile of the present invention can replace the approach right angle profile of prior technology to reduce the stress of the membrane deposited follow-up and to prevent the permanence mechanical damage of membrane peeling, membrane cracking result from the accumulating stress of membranes to improve the reliability and yield ration of the products of the processes.

A further object of the present invention is to present but also can broaden the follow-up processing window and improve the reliability and yield ration of the products of the follow-up processes.

In order to achieve previous objects of the invention, a method comprises following essential steps are presented as a preferred embodiment. In the present invention, a membrane is deposited on a semiconductor substrate, then after a photo-resist pattern transferring step, dry etching step, and photo-resist removing step, a patterned membrane element is formed thereon. Then, a sacrificing layer is formed conformally overlaying the patterned membrane element, wherein the sacrificing layer is step height according to the patterned membrane element. Following, an etching back step is performed to etch the sacrificing layer by selectivity etching to form a rounding profile of the coroner of the membrane element. Last, the residual sacrificing layer is removed.

Furthermore, the primary object of the present invention is to provide a semiconductor rounding profile for reducing step profile and manufacturing processing stress, wherein a rounding profile structure is not only used to reduce the stress of the semiconductor structure to be beneficial to the succeeding process, but also the stability of the element can be sustained without the problem induced from the yield ratio of the products.

Another object of the present invention is to provide a semiconductor rounding profile for reducing step profile and manufacturing processing stress, wherein not only maintains the stability of elements, but also the contact window in the lithographic process can be expanded so as to improve the tolerance in the succeeding process.

A further object of the present invention is to provide a semiconductor rounding profile for reducing step profile and manufacturing processing stress, wherein a plurality of elements covering on exposed surfaces of said elements with a rounding profile and said semiconductor substrate, and elements of rounding profile are used to replace a rectangular element with tips so as to improve the tolerance of the succeeding process.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic representation of the cross-section view of the semiconductor structure, in accordance with prior techniques;

FIG. 2 is a schematic representation of the cross-section view of various stages during the formulation of the rounding profile of the semiconductor structure, in accordance with prior techniques;

FIG. 3A and FIG. 3E are schematic representations of cross-section view of structures at various stages during the formulation of the rounding corner profile of the semiconductor structure during the formulation of the rounding corner profile of the semiconductor structure, in accordance with one preferred embodiment of the present invention;

FIG. 4 is a schematic view showing the prior art semiconductor memory;

FIG. 5 is a structural schematic view of the FIG. 4 with voids;

FIG. 6 is a structural schematic view showing a preferred embodiment of the present invention;

FIG. 7 is a schematic view showing a photo resistor layer forming on a surface of the third embodiment; and

FIG. 8 is a structural schematic view showing another embodiment of the present invention

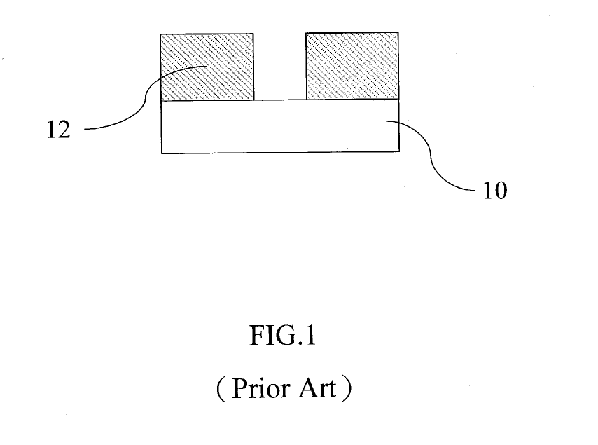

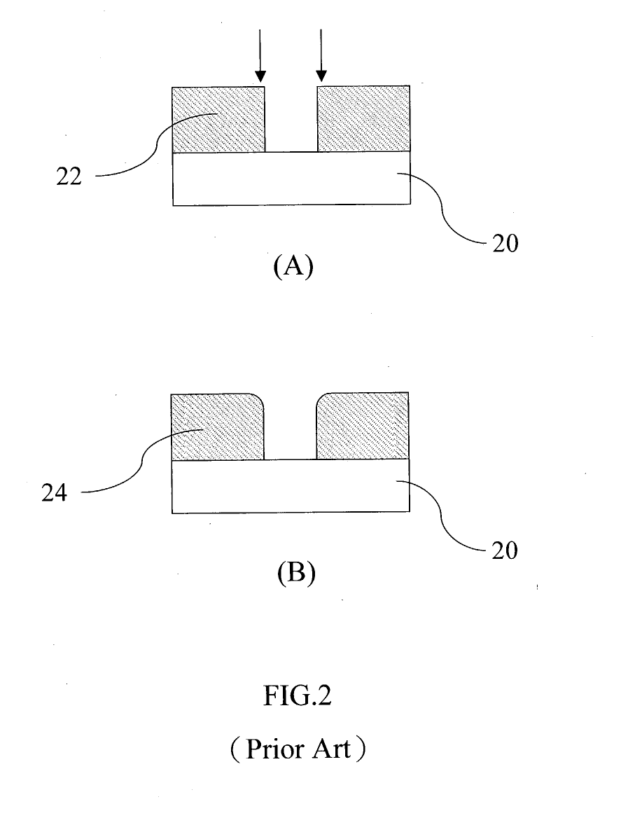

### DESCRIPTION OF THE PREFERRED EMBODIMENT

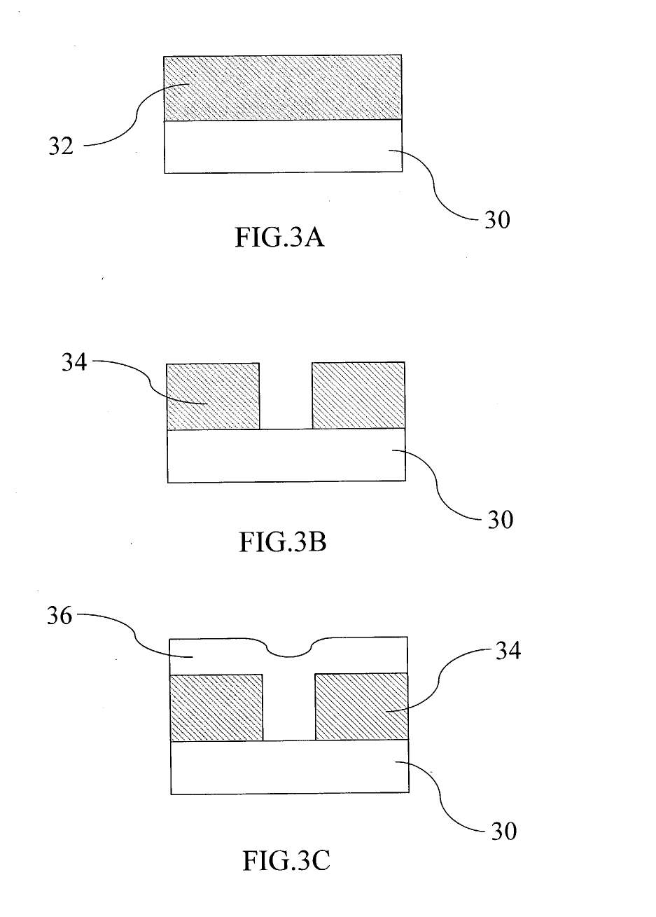

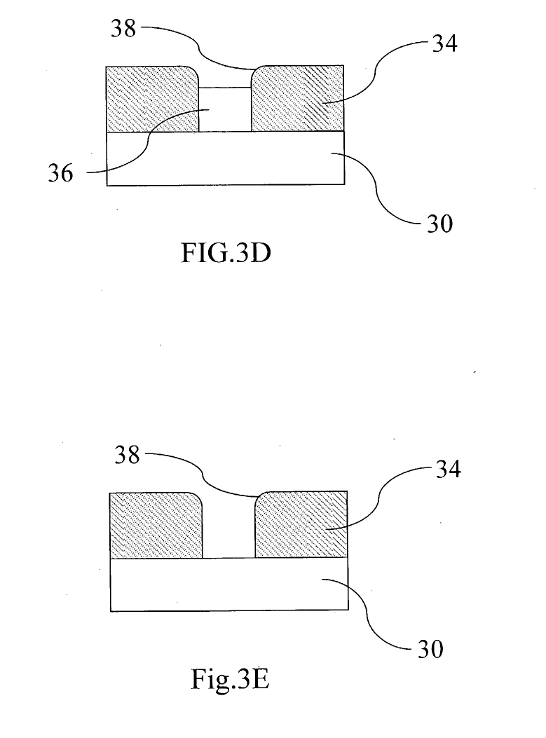

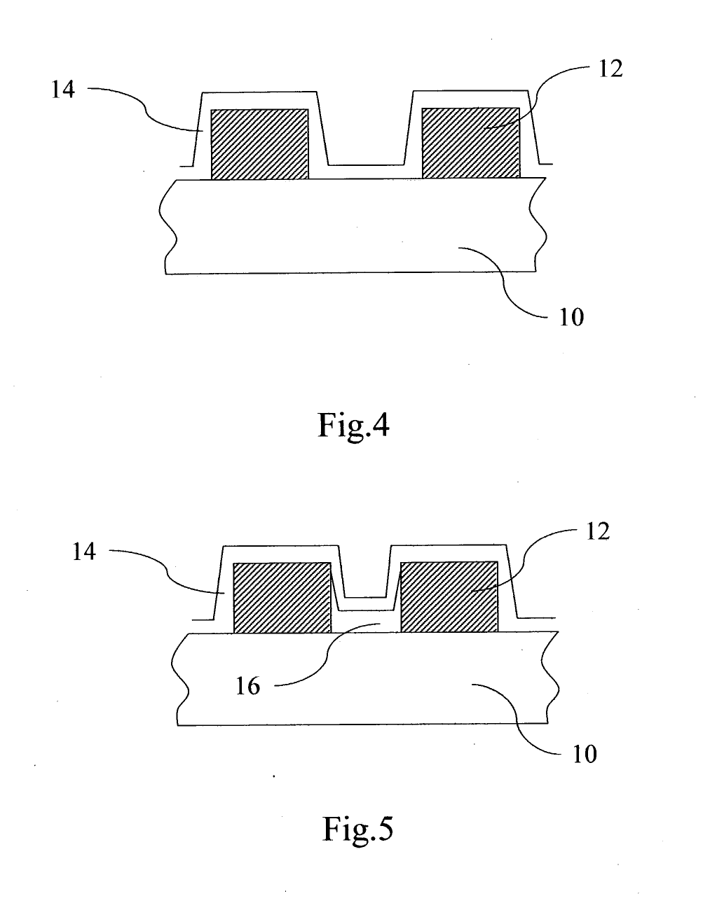

First, referring to the FIG. 3A to FIG. 3E, one preferred embodiment of the present method for rounding the corner of the membrane element in a semiconductor device is disclosed with schematic representations of cross-section view of structures at essential stages during the formulation of the rounding corner profile of the semiconductor structure.

Referring to the FIG. 3A, a semiconductor substrate 30 is provided and the semiconductor substrate is usually a silicon substrate. Then, a membrane 32 is formed on the semiconductor substrate 30 by using the chemical vapor deposition method, wherein the membrane 32 is usually the oxide, the silicon dioxide, the silicon nitride, the polysilicon, the metal-interconnect wires, the phosphosilicate glass (PSG), the borophosphosilicate glass (BPSG), the fluorinated silicate (FSG), tetraethylorthosilicate (TEOS), the silicon saturation silicon oxide, and etc., or consisted of other semiconductor devices.

Then, a photo-resist layer is deposited on the surface of the membrane element 32 and a patterned photo-resist layer is formed after a photolithography step. The patterned photo-resist layer is used as the mask to perform a dry etching process with the membrane element 32 and then the residual photo-resist layer is removed to form a plurality of membrane elements 34, such as shown in the FIG. 3B. Between membrane elements 34, a portion of the semiconductor substrate 30 is exposed. Wherein, the membrane elements 34 are formed by an anisotropic etching method, so the corner is provided with an almost 90 degrees right angle profile.

Such as shown in the FIG. 3C, on the exposed surface of the membrane elements 34 and the semiconductor substrate 30, a sacrificing layer of the organic component, such as the photo-resist layer 36, is conformally coated on the patterned membrane elements 34. the photo-resist layer 36 is usually coated by using the spin coating with the spinner, which the maximum rpm is between about 6,000 rmp to 7,000 rpm, wherein the thickness of the photo-resist layer 36 is about 1 micrometer and to rise and fall according to the patterned membrane elements 34. The photo-resist layer of the organic component mentioned above has the advantages of the characteristic of organic component, such as easily reworking, easily coating, and uniform conformity.

Following, referring to the 3D, an etching back process is performed to etch the photo-resist layer 36 on the membrane elements 34 until to expose the membrane elements 34 and only to retain the residual photo-resist layer 36 between membrane elements 34. Wherein, the etching back process is using the selectivity etching method so only the sharp portion of the corner of the membrane element 34 is etched to form the rounding profile 38 without over etching.

Last, referring to the FIG. 3E, the residual photo-resist layer 36 between membrane elements 34 is stripped by using the wet stripping method or the dry stripping method so as to obtain a membrane elements 34 with a rounding profile 38. Because the present invention provides with a rounding corner profile of the membrane element, so the present invention can to reduce the stress and the step height of membranes deposited follow-up and to broaden the follow-up processing window so as to improve the yield ration of the products and reliability of the processes.

Furthermore, the membrane elements 34 in the FIG. 3C also can be replaced by a stacking type gate electrode, wherein the gate electrode concludes an oxide layer, a polysilicon layer and tungsten silicide. Besides, membrane elements 34 can be replaced by a flash memory gate electrode concluding a tunneling channel oxide layer, a floating gate, a isolating dielectric layer, and a control gate.

Thus, to sum up the forgoing mentioned above, the present invention discloses a method for rounding a corner of a membrane element in a semiconductor device, wherein the rounding corner profile replaces the approach right angle profile of prior technology, to reduce the stress of follow-up deposited membrane and to solve the over etching problem of the prior technology with the difficult control of directly etching to form the rounding corner. The present invention utilizes the advantages of the characteristic of the organic component, such as easily reworking, easily coating, and uniform conformity, to use for the photo-resist layer of the present invention to helpful for following processes. Furthermore, the etching back step of the present invention is easily performed and matured developed so as further improving the following processes.

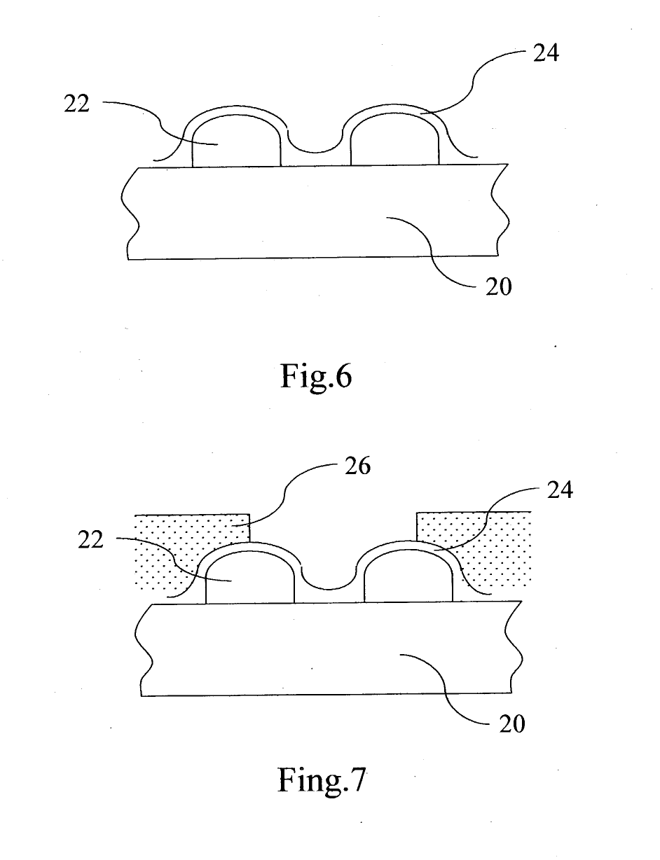

Referring to FIG. 6, in this embodiment, a plurality of BD oxide layer 22 with a rounding profile is formed on the semiconductor substrate 20. The function of the semiconductor substrate is to isolate the high concentration ion to be implanted. Next, a layer of borophosophosilicate glass (BPSG) or a dielectric layer 24 formed by silicon dioxide cover the exposed BD oxide layer 22 and the semiconductor substrate so that the shape of the dielectric layer 24 is formed with a rounding profile structure.

Therefore, when lithographic etching process is performed in the present invention, as illustrated in FIG. 7, a layer of photo resistor layer 26 is coated on the surface of the dielectric layer 24 and yellow light lithographic etching technology is used to form a patterned photo resistor layer 26 having a etching window 28 having a selected size for defining the size and position of a contact window to be etched. Then, a current etching technology is used to pattern the mask of the photo resistor layer 26 and then the dielectric layer 24 exposed from the etching window 28 is etched and removed. Therefore, by the structure of the BD oxide layer 22 with a rounding cross section and the dielectric layer 24 with a rounding profile, the succeeding process of the present invention has a lower stress and step height. Furthermore, the defects, such as cracks, voids, or pealing away can be avoided. Therefore, the present invention not only maintains the stability of elements, but also the contact window in the lithographic process can be expanded so as to improve the tolerance in the succeeding process.

Other than rounding profile of BD oxide layer 22 formed on the surface of the semiconductor substrate, other elements on the semiconductor substrate, such as the gate, may be formed with a refracting portion. These elements may be formed by polysilicon, and may include a tunneling oxide, a floating gate, a dielectric layer and a control gate.

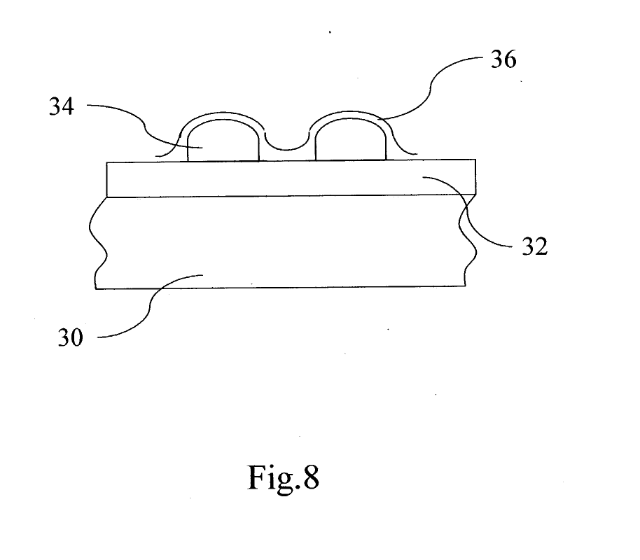

With reference to FIG. 8, a structural schematic view of another embodiment of the present invention is illustrated. As shown in the figure, in this embodiment, a semiconductor substrate 30 with a finished proceeding manufacturing process is provided. A MOS transistor layer 32 is formed thereon. A plurality of metal interconnect wires 34 having a rounding profile are formed on the semiconductor substrate 30. The metal interconnect wires 34 are made by one of aluminum, alloys of aluminum and copper, alloys of aluminum, silicon and copper or copper. Finally, an dielectric layer 36 cover the exposed surfaces of the plurality of metal interconnect wire 34 with rounding profile and the semiconductor substrate 30. In general, the dielectric layer 36 are one of Phosphosilicate Glass, (PSG), or Fluorosilicate Glass (FSG) or Low K Dielectric or silicon oxide, or Tetraethyl-orthosilicate (TEOS). The semiconductor structure of metal interconnect wires 34 having a rounding profile used in the present invention may not only avoid the permanent mechanical damage due to an overlarge accumulated stress in the dielectric layer 36, but also the step height in the semiconductor structure may be reduced. These are beneficial to the succeeding process.

Since in the present invention, elements of rounding profile are used to replace a rectangular element with tips, the problem of a too large stress at the upper surface and lateral sides of the prior art elements to induce cracks, hillocks, or pealing effect can be avoided. Therefore, the rounding profile structure is not only used to reduce the stress of the semiconductor structure to be beneficial to the succeeding process, but also the stability of the element can be sustained without the problem induced from the yield ratio of the products. Furthermore, the semiconductor structure with a rounding profile have no the problem of a too large step height in the dielectric layer 14 of the prior art semiconductor element (this will induce the defects of a too small window, exposure in focusing, difficulty in the succeeding process. Furthermore, the step height in the semiconductor structure is reduced and the window in succeeding lithographic and etching processes can be expanded so as to improve the tolerance of the succeeding process.

Besides, even the size of the element is decreased, the semiconductor structure with a rounding profile according to the present invention has the problem illustrated in FIG. 5, i.e., in the prior art, the distance between to elements are reduced further so that the next thin film deposition of the dielectric layer tends to generate voids in gaps. Therefore, the present invention induces no unfavorable effect to the succeeding process.

Of course, it is to be understood that the invention described herein need not be limited to these disclosed embodiments. Various modification and similar changes are still possible within the spirit of this invention. In this way, all such variations and modifications are included within the intended scope of the invention and the scope of this invention should be defined by the appended claims.

1-10. (canceled).

11. A semiconductor device having a rounding profile structure for reducing step profile and manufacturing processing stress comprising:
a semiconductor substrate;
a plurality of elements covering on exposed surfaces of said elements with a rounding profile and said semiconductor substrate.

12. The semiconductor device having a rounding profile structure claimed in claim 11, wherein said element is a gate.

13. The semiconductor device having a rounding profile structure as claimed in claim 11, wherein said gate is formed by a tunneling oxide, a floating gate, an insulating dielectric layer, and a control gate.

14. The semiconductor device having a rounding profile structure as claimed in claim 11, wherein said floating gate is formed by polysilicon material.

15. The semiconductor device having a rounding profile structure claimed in claim 11, wherein said element is a BD oxide layer 22.

16. The semiconductor device having a rounding profile structure as claimed in claim 11, wherein said dielectric layer is selected from one of a group containing silicon oxide, or tetraethyl-orthosilicate, boronitrosilicate glass, or nitrosilicate glass.

17. A semiconductor device having a rounding profile structure for reducing step profile and manufacturing processing stress, comprising:
a semiconductor substrate having finished basic elements;
a plurality of metal interconnect wires with rounding profile being positioned in said semiconductor substrate; and
a dielectric layer covering exposed surfaces of said metal interconnect wires and said semiconductor substrate.

18. The semiconductor device having a rounding profile structure as claimed in claim 17, wherein metal interconnect wires are made from one of a group containing aluminum, alloys of aluminum and copper, alloys of aluminum, silicon and copper, and copper.

19. The semiconductor device having a rounding profile structure as claimed in claim 17, wherein said dielectric layer is selected from one of a group containing silicon oxide, or tetraethyl-orthosilicate, boronitrosilicate glass, or nitrosilicate glass.

20. The semiconductor device having a rounding profile structure as claimed in claim 17, wherein the dielectric layer has a low dielectric constant.
